(19) United States
(12) Patent Application Publication
(10) Pub. No.: US 2026/0090337 A1
(43) Pub. Date: Mar. 26, 2026

(54) MACHINE LEARNING BASED VIRTUAL SENSING OF WAFER TEMPERATURES DURING REFLOW PROCESS IN A PHYSICAL VAPOR DEPOSITION CHAMBER WITH UNCERTAIN CHAMBER PHYSICAL PROPERTIES AND VARYING OPERATING CONDITIONS

(71) Applicant: Applied Materials, Inc., Santa Clara, CA (US)

(72) Inventors: Preetham RAO, Morgan Hill, CA (US); Suhas UMESH, Santa Clara, CA (US); Martin Lee RIKER, Milpitas, CA (US); Fuhong ZHANG, San Jose, CA (US); Kishor KALATHIPARAMBIL, Santa Clara, CA (US)

(21) Appl. No.: 18/890,876

(22) Filed: Sep. 20, 2024

(51) Int. Cl. H01L 21/66; G01K 3/10; G01K 3/14; G05B 13/02

(52) U.S. Cl. CPC H10P 74/238; G01K 3/10; G01K 3/14; G05B 13/0265; G01K 2213/00

(57) ABSTRACT

Methods and devices for determining a temperature of a substrate during processing are provided herein. Embodiments include extracting modes from a virtual model of thermal conditions within a processing chamber. Embodiments further include receiving thermal sensor data associated with a target substrate. Embodiments further include using compressed sensing to generate a thermal map for the target substrate based on the thermal sensor data and the extracted modes.

### BACKGROUND

### Field

Embodiments of the present invention generally relate to monitoring the temperature of a substrate during substrate processing.

### Description of the Related Art

While processing substrates, such as silicon wafers used to manufacture integrated circuits, it may be beneficial to monitor the temperature of the substrates. For example, during a deposition process (e.g., physical vapor deposition, a process through which a copper layer is deposited on the surface of the substrate), variations in temperature may occur across the surface of the substrate (e.g., the temperature at one or more locations on the surface of the substrate may differ from a temperature required by a processing recipe). These variations may result in imperfections in the processed substrate.

However, accurately determining the temperature of the surface of the substrate during processing poses many technical challenges. For example, using sensors to directly detect the temperature of the entire substrate surface can be very difficult and inefficient due to factors such as infrared pollution, extremely low pressure inside a processing chamber, and space constraints.

Thus, there is a need in the art for a method and system of monitoring the temperature of a substrate during substrate processing using a limited number of sensor measurements.

### SUMMARY

In one embodiment, a method of determining the temperature of a substrate during processing includes extracting spatio-temporal modes from a virtual model of thermal conditions within a processing chamber. The method further includes receiving thermal sensor data associated with a target substrate. The method further includes using compressed sensing to generate a thermal map for the target substrate based on the thermal sensor data and the extracted modes.

Other embodiments provide processing systems configured to perform the aforementioned method as well as those described herein; non-transitory, computer-readable media comprising instructions that, when executed by one or more processors of a processing system, cause the processing system to perform the aforementioned methods as well as those described herein; a computer program product embodied on a computer readable storage medium comprising code for performing the aforementioned methods as well as those further described herein; and a processing system comprising means for performing the aforementioned methods as well as those further described herein.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a schematic side cross-sectional view of a processing chamber 100, according to one or more embodiments.

FIG. 2 depicts an example of computing components used for determining the temperature of a substrate during processing.

FIG. 3 depicts experimental results demonstrating the accuracy of embodiments disclosed herein.

FIG. 4 is a flowchart of a method of determining the temperature of a substrate during processing according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to real-time estimations (e.g., “virtual sensing”) of substrate temperature within a semiconductor processing system. A virtual model, which may encompass or utilize system modeling algorithms and processing chamber geometry, may be generated based on ground truth measurements of thermal conditions within a processing chamber. Modes may be extracted from the virtual model by, for example, using proper orthogonal decomposition or other machine learning techniques. Then, compressed sensing techniques may be used to generate a thermal map of the substrate based on the extracted modes and real-time temperature data received from a single sensor or multiple sensors within the processing chamber during processing (e.g., a reflow process during physical vapor decomposition). The techniques disclosed herein thus allow for accurately determining the temperature across the surface of a substrate during processing using only a limited number of sensors.

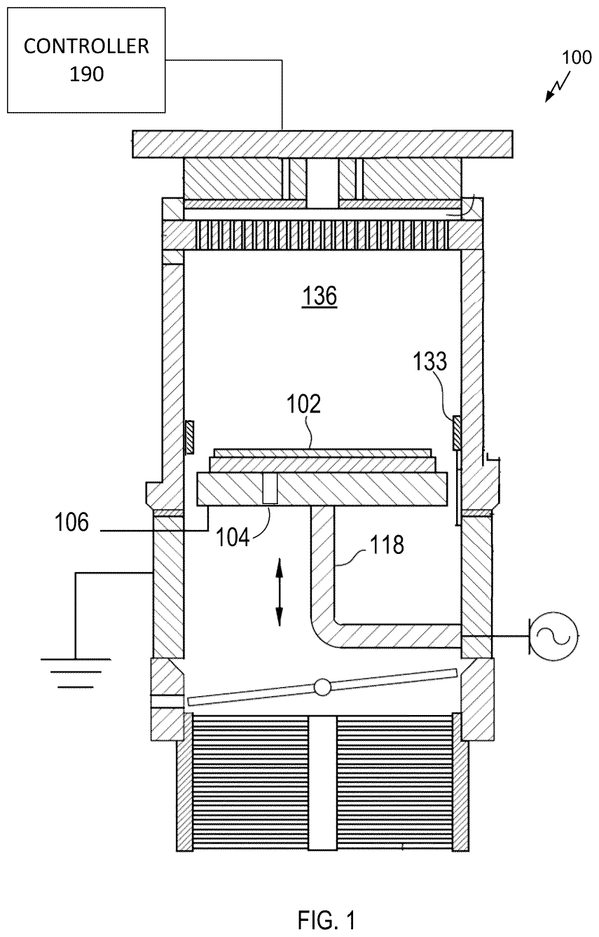

FIG. 1 is a schematic side cross-sectional view of a processing chamber 100, according to one or more embodiments. The processing chamber 100 may be a deposition chamber, such as a physical vapor deposition (PVD) chamber. The processing chamber 100 may be utilized to grow an epitaxial film on a substrate 102. The processing chamber 100 creates a cross-flow of precursors across a top surface of the substrate 102.

The processing chamber 100 includes processing volume 136, a cavity in which the substrate 102 is processed. Disposed within processing volume 136 is a substrate support 106 and a ring heater 133. The ring heater 133 is located along the circumference of the processing volume 136 and is configured to apply heat to the substrate during processing. The ring heater 133 may be used to heat the substrate 102 according to a given substrate processing recipe.

The substrate support 106 may comprise a platform that supports the substrate 102 within the processing volume 136. In one or more embodiments, the substrate support 106 includes a susceptor connected to the substrate support 106 by a shaft 118. Other substrate supports (including, for example, a substrate carrier and/or one or more ring segment(s) that support one or more outer regions of the substrate 102) are contemplated by the present disclosure. On or more lift pins may be used to lift the substrate 102 relative to the surface of the substrate support 106 and lower the substrate 102. The substrate support 106 may be raised/lowered within the processing volume 136, such as by the susceptor.

One or more thermal sensors 104 may be used to determine temperatures associated with the substrate 102. For example, the thermal sensor 104 shown in FIG. 1 is located on the substrate support 106. The temperature of the substrate 102 during processing may be directly measured by a sensor 104, or the sensor 104 may be used to measure the temperature of the substrate 102 by proxy. Proxy temperature measurements refer to measuring the temperature of an object near the substrate 102 (e.g., the ring heater 133 or the substrate support 106). According to embodiments disclosed herein, direct and/or proxy temperature measurements may be used to calculate the temperature of the substrate 102.

As shown, a controller 190 is in communication with the processing chamber 100 and is used to control processes and methods, such as the operations of the methods described herein.

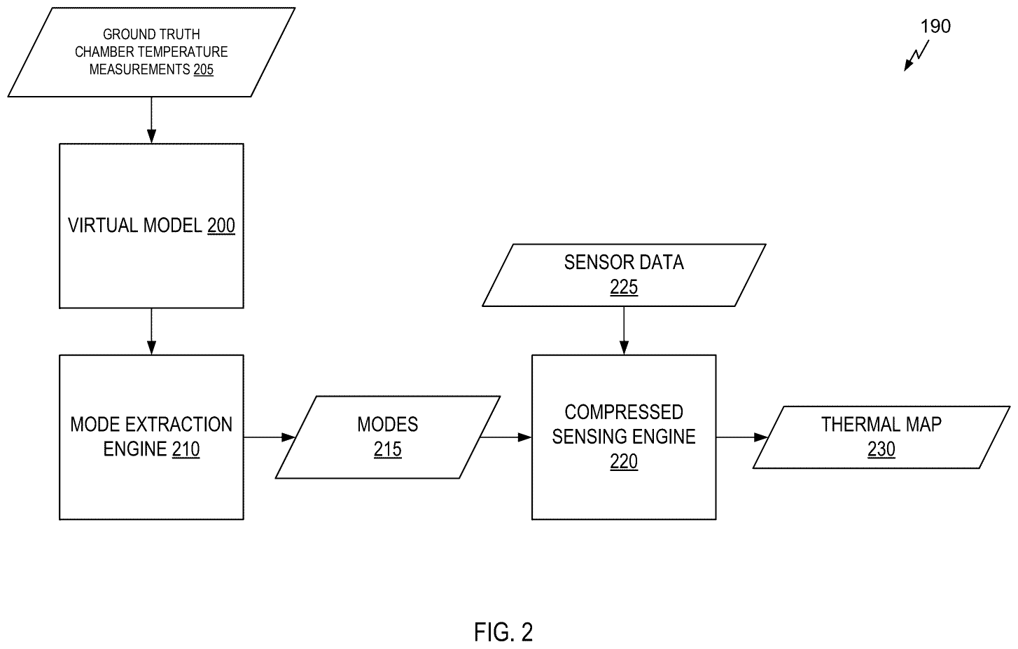

The controller 190 is configured to receive data or input as sensor readings from a plurality of sensors. The sensors can include sensor 104 shown in FIG. 1. As discussed in further detail below with respect to FIG. 2, the controller 190 may equipped with or in communication with a virtual model 200 of the processing chamber. The controller 190 may further include a mode extraction engine 210 that is configured to extract modes 215 from the virtual model 200. The controller 190 may be further equipped with a compressed sensing engine 220 that is configured to use a compressed sensing algorithm to construct a thermal map 230 of the substrate surface based on data from the sensor 104 and the modes 215.

The controller 190 facilitates monitoring of system conditions, estimates parameters, controls processing operations or recipe parameters, generates an alert on a display, halts a deposition operation, initiates a chamber downtime period, delays a subsequent iteration of the deposition operation, initiates a cleaning operation, halts the cleaning operation, adjusts a heating power, and/or otherwise adjusts the process recipe. The controller 190 may be used to control various other components of the processing chamber. For example, the controller 190 may be used to raise or lower the lift pins 108 or the substrate support 106.

The controller 190 may be for a specific process chamber, a set of process chambers, or a semiconductor processing tool as a whole. The controller 190 includes a central processing unit (CPU) (e.g., a processor), a memory containing instructions, and support circuits for the CPU. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 190 are coupled to the CPU for supporting the CPU. The support circuits include cache, power supplies, clock circuits, input/output circuitry and subsystems, and the like. Operational parameters, simulations, and machine learning algorithms are stored in the memory as software routines that are executed or invoked to turn the controller 190 into a specific purpose controller to control the operations of the various chambers/modules described herein. The controller 190 is configured to conduct any of the operations described herein. While embodiments herein describe certain aspects as stored locally on memory, it is contemplated that one or more aspects may be stored remotely and accessed via a data connection.

FIG. 2 illustrates example computing components used for determining the temperature of a substrate during processing. The computing components may be implemented using controller 190.

Ground truth chamber temperature measurements 205 may be used to create a virtual model 200 of thermal conditions within a processing chamber. The ground truth measurements 205 may be direct measurements of the temperature of a substrate and components within the processing chamber during processing. For example, a specialized sensor component such as a thermocouple wafer may be used to directly measure the temperature of a substrate during processing (e.g., a thermocouple wafer may be used in the place of a substrate during processing). In an example embodiment, the virtual model may be created based on directly measuring the temperature of a thermocouple wafer at various points along one or more radii of the thermocouple wafer.

The ground truth temperature measurements 205 may comprise temperature measurements as a function of time. The measurements 205 may be taken for various processing recipes and various chamber configurations such that the virtual model 200 can accurately represent the thermal conditions of the chamber for different configurations and recipes. For example, ground truth measurements 205 may be taken for different lift pin and pedestal positions. Thus, configurations such as lift pin height, pedestal height, and/or process recipe may be provided as input to the virtual model to obtain data from the virtual model 200 corresponding to those configurations. As discussed in further detail below, modes may be extracted from the data received from the virtual model and used to determine the temperature of a substrate during processing.

The virtual model 200 may be created based on using one or more techniques such as system modeling algorithms. Methods of system modeling using a system modeling algorithm generally utilize one or a combination of finite element modeling, finite volume modeling, finite difference modeling, fluid dynamics modeling (e.g., Navier-Stokes equations), process parameters, physics constraints (e.g., conservation of mass/energy equations), material qualities and dimensions, empirical data, and other factors, to model behavior of a processing system and environment. The model may solve for governing equations relevant to the processing chamber, such as fluid dynamics equations, energy equations, thermal equations, and electric/magnetic field equations. The model may also solve for estimated values of the temperature and thermal gradients at various points within the processing system. For example, ground truth chamber temperature measurements 205 may be taken at various locations throughout the processing chamber, and system modeling algorithms may be used to extrapolate the temperatures at other locations.

Mode extraction engine 210 may be used to reduce the order of the virtual model 200 into a set of dominant features known as modes 215. Mode extraction engine 210 may extract the modes 215 based on applying a decomposition algorithm to data within the virtual model 200. For example, a Fourier transform or proper orthogonal decomposition may be applied to the data to extract modes from the data. In an example of proper orthogonal decomposition, a matrix X containing data from the virtual model 200 may be represented as X=UΣV^{T}, where: X is a M×N matrix of the data from the virtual model 200; U is a M×M real orthogonal matrix and the columns of U are the eigenvectors of XX^{T}; Σ is an M×N diagonal matrix with the square roots of the non-zero eigenvalues of X^{T}X and XX^{T} on the diagonal; and V is a N×N real orthogonal matrix and the columns of U are the eigenvectors of X^{T}X. K-rank approximation can be applied to X such that U and V can be truncated after the k^{th} column, resulting in U′, V′, and Σ′, the k×k truncation of Σ. The columns of U′ represent the modes of the columns of X, and the columns of V′ represent the modes of the rows of X. The modes may be used to construct the thermal map 230, as discussed below.

In another example decomposition process, a matrix X containing data from the virtual model 200 may be represented in a k rank approximation as X=RΛb, where the columns of R are modes of X, Λ is a Vandermonde matrix composed from decomposition eigenvalues λⱼ, and the vector b determines the weighting of each of the k modes. According to some embodiments, the modes may be extracted using a machine learning model, such as a neural network or shallow neural network.

In some embodiments, the modes 215 are extracted based on providing processing chamber configurations as input to the virtual model 200. For example, a user may wish to measure the temperature of a substrate that is in a chamber with a particular lift pin height. The particular lift pin height may be provided as input to the virtual model 200 such that the data provided to mode extraction engine 210 will be data corresponding to a substrate that is processed using that lift pin height.

The modes 215 may be extracted from the data received from the virtual model 200. Then, the modes 215 may be provided as input to the compressed sensing engine 220. Sensor data 225 may also be provided as input to the compressed sensing engine 220. The sensor data may be data obtained from sensor 104 of FIG. 1 in real-time as a substrate is being processed. For example, the sensor data 225 may comprise a temperature value as a function of time. The compressed sensing engine 220 may use a compressed sensing algorithm to construct a thermal map 230 for the substrate based on the extracted modes 215 and the sensor data 225.

Compressed sensing generally relates to techniques for reconstructing signals by finding solutions to underdetermined linear systems. Using a compressed sensing algorithm, a signal with known modes may be reconstructed based on sparse data points. For example, for a given waveform S=5*sin(1.6t)+4*cos(2t)+2*sin²(t), if it is known that a waveform is the sum of sin(1.6t), cos(2t), sin2(t) terms, only three points along the waveform are necessary to reconstruct the entire signal using compressed sensing.

Similarly, the sensor data 225 and modes 215 of the virtual model 200 may be used to construct a thermal map 230 for the substrate. When compressed sensing is applied to the modes 215 along with the sensor data 225, a thermal map 230 may be constructed. Since the modes 215 of the virtual model 200 may be approximately identical to the modes of the actual chamber during processing, the thermal map 230 may represent an accurately constructed thermal signal of the entire substrate surface.

In an example compressed sensing process as known in the art, a matrix Y may contain a complete set of measurement values (e.g., the temperature values across the entire surface of a substrate) and a matrix X may contain a subset of the values in Y (e.g., temperature values at points along the surface that are actually measured by sensors). X may be mapped to Y by a matrix φ, such that X=φY. The complete matrix of values Y may be approximated as Y=ψA, where ψ is a matrix containing the modes of Y and A is a matrix containing scalar values. Thus, X may be approximated as X=φψA. For underdetermined linear systems (e.g., systems where the number of modes exceeds the number of sensors), the solution to the equation X=φψA for A that minimizes the L₁ norm of A may be calculated. This solution for A may be used to reconstruct Y based on the equation Y=ψA.

In embodiments disclosed herein, X may represent the sensor data 225 at a particular moment in time. ψ may represent the modes 215 extracted from the virtual model 200. φ may be a matrix that is used to map X to Y (e.g., a matrix that is based on the location of the sensors used to obtain the sensor data 225). The solution to the equation X=φψA that minimizes the L₁ norm of A may be calculated. The calculated solution to A may be used to solve the equation Y′=ψA for Y′. Y′ in this example may be used as the values for the thermal map 230 at the particular moment in time (e.g., an instantaneous thermal map). This process may be repeated for other moments in time to construct a full thermal map 230 that includes temperatures as a function of time.

In some embodiments, machine learning techniques may be used to construct the thermal map 230. For example, the modes 215 and sensor data 225 may be provided to a machine learning model (e.g., a neural network or shallow neural network) that is trained to construct thermal maps 230 based on modes and sensor data. The machine learning model may be trained through a supervised learning process. Supervised learning techniques generally involve providing training inputs to a machine learning model, such as a neural network. The machine learning model processes the training inputs and outputs predictions based on the training inputs. The predictions are compared to the known labels associated with the training inputs to determine the accuracy of the machine learning model, and parameters of the machine learning model are iteratively adjusted until one or more conditions are met. For instance, the one or more conditions may relate to an objective function (e.g., a cost function or loss function) for optimizing one or more variables (e.g., model accuracy). In some embodiments, the conditions may relate to whether the outputs produced by the machine learning model based on the training inputs match the known labels associated with the training inputs or whether a measure of error between training iterations is not decreasing or not decreasing more than a threshold amount. The conditions may also include whether a training iteration limit has been reached. Parameters adjusted during training may include, for example, hyperparameters, values related to numbers of iterations, weights, functions used by nodes to calculate scores, and/or the like. In some embodiments, validation and testing are also performed for a machine learning model, such as based on validation data and test data, as is known in the art.

The supervised learning process for a machine learning model used to generate the thermal map 230 may comprise providing the machine learning model with modes and sensor data. Parameters of the machine learning model may be iteratively adjusted based on variances between a thermal map generated by the machine learning model and a ground truth thermal map (e.g., until the output of the machine learning model matches the ground truth thermal map or until some other condition occurs). The supervised learning process for a machine learning model used to extract modes 215 from the virtual model 200 may comprise providing the machine learning model with data from a virtual model. Parameters of the machine learning model may be iteratively adjusted based on variances between modes generated by the machine learning model and a ground truth mode (e.g., until the output of the machine learning model matches the ground truth mode or until some other condition occurs).

The thermal map 230 may comprise a matrix of temperature values that represent temperatures associated with a substrate (e.g., temperatures across the surface of the substrate). The thermal map 230 may further comprise time series data (e.g., multiple matrices that represent the thermal conditions associated with the substrate as a function of time). In some embodiments, the matrix may be used to create a visual (e.g., color-coded) map of the substrate that can be presented to users of a substrate processing system via a user interface. The users may use the thermal map 230 to perform actions regarding substrate processing, as discussed below. In other embodiments, a computing system such as controller 190 may be configured to automatically perform actions regarding substrate processing based on the thermal map 230, as discussed below.

The thermal map 230 may be used to perform various actions involving substrate processing. For example, the thermal map 230 may indicate that the temperatures of the substrate varied from temperatures required by a processing recipe. Such variations may lead to impurities and/or other imperfections in the substrate. As a result, one or more components of the chamber may be adjusted. For instance, heating components may be adjusted, the position of the substrate may be adjusted (e.g., by raising/lowering the lift pins and/or substrate support), and/or other components of the processing chamber may be adjusted. Additionally, the processed substrate may be discarded if the thermal map 230 indicates that imperfections likely occurred (e.g., based on the thermal map 230 indicating that the temperature of the substrate deviated from a processing recipe).

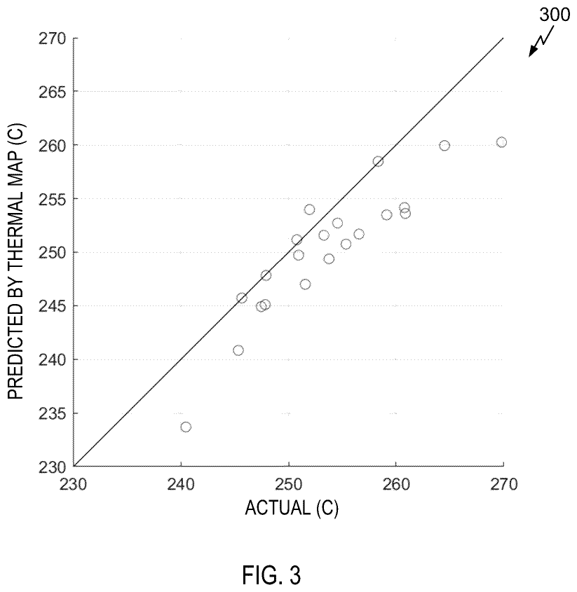

FIG. 3 illustrates experimental results 300 demonstrating the accuracy of embodiments disclosed herein. As shown in FIG. 3, the temperature indicated by the exemplary thermal maps is generally relatively close to the actual measured temperatures of substrates during processing. In some examples, the thermal map temperature is a near-to-exact match with the actual temperature.

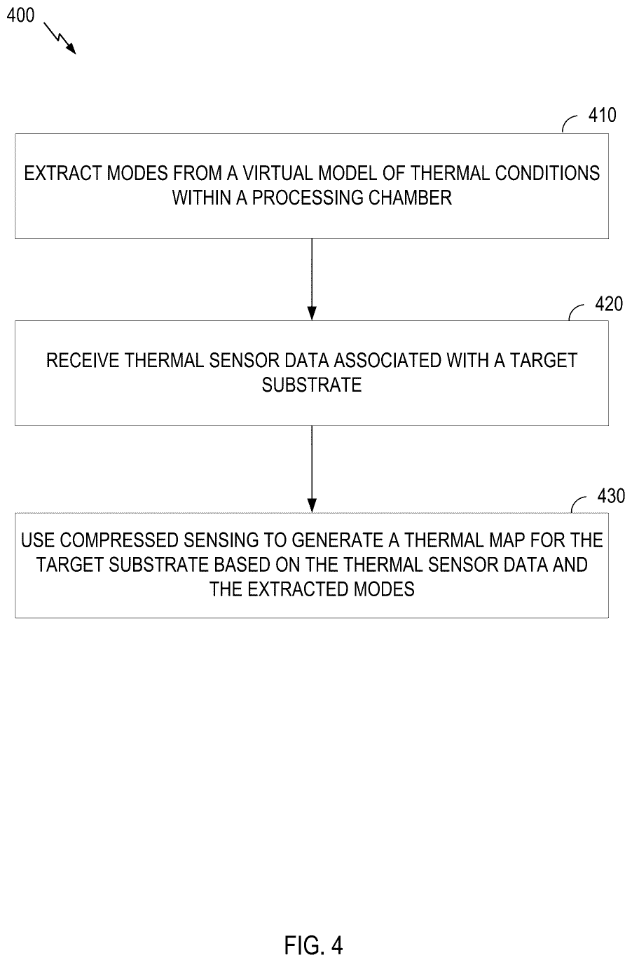

FIG. 4 is a flow diagram of example operations 400 for determining the temperature of a substrate during processing. Operations 400 may be performed by a computing device comprising one or more processors, such as the controller 190 as discussed with respect to FIGS. 1 and 2.

Operations 400 begin at 410, with extracting modes from a virtual model of thermal conditions within a processing chamber. In certain embodiments, extracting the modes is based on using proper orthogonal decomposition. Certain embodiments provide that the modes are extracted using a neural network. In some embodiments, the virtual model is created based on measuring temperature values associated with substrate processing. Certain embodiments provide that extracting the modes is based on providing a position of the target substrate as an input to the virtual model, wherein the modes are based on the position. In certain embodiments, the virtual model is created based on temperature measurements associated with multiple processing recipes.

Operations 400 continue at 420, with receiving thermal sensor data associated with a target substrate. According to some embodiments, the thermal sensor data comprises a temperature measurement as a function of time. Some embodiments provide that the thermal sensor data comprises temperature measurements from multiple sensors. In certain embodiments, one of the sensors measures a temperature of a component associated with the processing chamber.

Operations 400 continue at 430, with using compressed sensing to generate a thermal map for the target substrate based on the thermal sensor data and the extracted modes.

According to some embodiments, one or more actions may be performed based on the generated thermal map, such as adjusting a position of a substrate support within the processing chamber; adjusting heating components within the processing chamber; adjusting other components of the processing chamber; or discarding a processed substrate.

While the foregoing is directed to implementations of the present disclosure, other and further implementations of the disclosure may be devised without departing from the basic scope thereof, and the scope thereof is determined by the claims that follow.

What is claimed is:

1. A method for determining a temperature of a substrate during processing, comprising:
extracting modes from a virtual model of thermal conditions within a processing chamber;
receiving thermal sensor data associated with a target substrate; and
using compressed sensing to generate a thermal map for the target substrate based on the thermal sensor data and the extracted modes.

2. The method of claim 1, further comprising performing, based on the generated thermal map, one or more of:
adjusting a position of a substrate support within the processing chamber;
adjusting heating components within the processing chamber;
adjusting other components of the processing chamber; or
discarding a processed substrate.

3. The method of claim 1, wherein extracting the modes is based on using proper orthogonal decomposition.

4. The method of claim 1, wherein the modes are extracted using a neural network.

5. The method of claim 1, wherein the virtual model is created based on measuring temperature values associated with substrate processing.

6. The method of claim 1, wherein extracting the modes is based on providing a position of the target substrate as an input to the virtual model, wherein the modes are based on the position.

7. The method of claim 1, wherein the virtual model is created based on temperature measurements associated with multiple processing recipes.

8. The method of claim 1, wherein the thermal sensor data comprises a temperature measurement as a function of time.

9. The method of claim 1, wherein the thermal sensor data comprises temperature measurements from multiple sensors.

10. The method of claim 9, wherein one of the sensors measures a temperature of a component associated with the processing chamber.

11. A method for determining a temperature of a substrate during processing, comprising:
using proper orthogonal decomposition to extract modes from a virtual model of thermal conditions within a processing chamber, wherein the virtual model is created based on measuring temperature values associated with substrate processing, wherein a position of a target substrate is provided as an input to the virtual model;
receiving thermal sensor data associated with the target substrate, wherein the thermal sensor data comprises a temperature measurement as a function of time;
generating a thermal map for the target substrate based providing the thermal sensor data and the extracted modes as inputs to a compressed sensing algorithm; and
performing one or more actions relating to processing substrates based on the thermal map.

12. A computer readable medium, storing instructions that when executed by a processor of a system, cause the system to:
extract modes from a virtual model of thermal conditions within a processing chamber;
receive thermal sensor data associated with a target substrate; and
use compressed sensing to generate a thermal map for the target substrate
based on the thermal sensor data and the extracted modes.

13. The computer readable medium of claim 12, further comprising performing, based on the generated thermal map, one or more of:
adjusting a position of a substrate support within the processing chamber;
adjusting heating components within the processing chamber;
adjusting other components of the processing chamber; or
discarding a processed substrate.

14. The computer readable medium of claim 12, wherein extracting the modes is based on using proper orthogonal decomposition.

15. The computer readable medium of claim 12, wherein the modes are extracted using a neural network.

16. The computer readable medium of claim 12, wherein the virtual model is created based on measuring temperature values associated with substrate processing.

17. The computer readable medium of claim 12, wherein extracting the modes is based on providing a position of the target substrate as an input to the virtual model, wherein the modes are based on the position.

18. The computer readable medium of claim 12, wherein the thermal sensor data comprises a temperature measurement as a function of time.

19. The computer readable medium of claim 12, wherein the thermal sensor data comprises temperature measurements from multiple sensors.

20. The computer readable medium of claim 19, wherein one of the sensors measures a temperature of a component associated with the processing chamber.
